(19) United States
(12) Patent Application Publication
(10) Pub. No.: US 2015/0102802 A1
(43) Pub. Date: Apr. 16, 2015

(54) OPTICAL FIBER CURRENT SENSOR

(71) Applicant: ELECTRONICS AND TELECOMMUNICATIONS RESEARCH INSTITUTE, Daejeon (KR)

(72) Inventors: Hyoungjun PARK, Gwangju (KR); Young Soon HEO, Gwangju (KR); Kwon-Seob LIM, Gwangju (KR); Keo-Sik KIM, Gwangju (KR); Eun Kyoung JEON, Gwangju (KR); Jeong Eun KIM, Gwangju (KR); Hyun Seo KANG, Gwangju (KR); Young Sun KIM, Gwangju (KR)

(73) Assignee: ELECTRONICS AND TELECOMMUNICATIONS RESEARCH INSTITUTE, Daejeon (KR)

(21) Appl. No.: 14/172,533

(22) Filed: Feb. 4, 2014

(30) Foreign Application Priority Data
Oct. 16, 2013 (KR) 10-2013-0123560

(51) Int. Cl. G01R 19/00

(52) U.S. Cl. CPC G01R 19/0092
USPC 324/97

(57) ABSTRACT

An optical fiber current sensor includes a transmitter optical subassembly (TOSA) that is formed in a package of a linear polarizer that applies light from a light source to a sensor coil that is formed with an optical fiber by linearly polarizing, a polarization beam splitter that separates light that is reflected from the sensor coil according to polarization, and a receiver optical subassembly (ROSA) that is formed in a package together with first and second photodetectors that detect separated light according to polarization.

### CROSS-REFERENCE TO RELATED APPLICATION

This application claims priority to and the benefit of Korean Patent Application No. 10-2013-0123560 filed in the Korean Intellectual Property Office on Oct. 16, 2013, the entire contents of which are incorporated herein by reference.

### BACKGROUND OF THE INVENTION

(a) Field of the Invention

The present invention relates to an optical fiber current sensor. More particularly, the present invention relates to a transistor outline (TO)-CAN-based micro-optical fiber current sensor for easy measurement of a high current and a high voltage.

(b) Description of the Related Art

An optical current transformer (CT), i.e., an optical current sensor, can easily form a more stable measurement system in a high voltage and high current situation, compared with an existing electromagnetic field CT by insulation and non-inductivity of a used optical element. Further, because the optical CT does not use an iron core, there is a merit that the optical CT is free of influence of magnetic saturation or residual magnetism.

The optical CT may be divided into a bulk type and an optical fiber type according to a form of an optical component using as a sensor, and there is a merit that the optical fiber type optical CT can reduce an influence of external noise by easily embodying a closed-loop type sensor and can freely adjust a range of current measurement and sensitivity by adjusting the rotation number of a coil. However, an asymmetrical structure of an optical fiber, or linear birefringence that is generated by bending in a process of manufacturing a coil, may operate as an element that makes it difficult to apply an optical CT to the spot by distorting a polarizing state of an optical signal. Therefore, domestic and foreign conventional researches have been performed in a direction that minimizes an influence of linear birefringence using a heat-treated optical fiber coil, a flint glass optical fiber coil in which much lead is added, and a coil that is made of a twisted optical fiber. Each technique has a merit, but because mechanical strength of a coil after a heat treatment is deteriorated or transmission loss (2.5 dB/m) of a flint glass fiber is so large, there is a drawback that it is difficult to use the flint glass fiber with a sensor coil of 5 m or more, by uniformly twisting an optical fiber, and that it is difficult to stably fix the optical fiber.

### SUMMARY OF THE INVENTION

The present invention has been made in an effort to provide an optical fiber current sensor having advantages of being capable of being mass-produced with a low cost by simplifying a structure and manufacturing in a microsize.

An exemplary embodiment of the present invention provides an optical fiber current sensor that measures a current that flows to a conductor using a sensor coil that is formed with an optical fiber. The optical fiber current sensor includes a transmitter optical subassembly (TOSA) and a receiver optical subassembly (ROSA). The TOSA polarizes light from a light source and applies the light to the sensor coil. The ROSA separates light that is reflected from the sensor coil according to polarization, and detects the separated light according to polarization. The TOSA and the ROSA are formed in a transistor outline (TO)-CAN package.

The TOSA may include a linear polarizer that is formed on a first TO-CAN stem and that linearly polarizes light from the light source and applies the light to the sensor coil.

The ROSA may include a polarization beam splitter that is formed on a second TO-CAN stem and that separates light that is reflected from the sensor coil according to polarization, and first and second photodiodes that are each formed on the second TO-CAN stem and that detect separated light according to polarization.

The ROSA may further include a reflecting mirror that reflects one of the separated lights according to polarization and that applies the light to a second photodiode.

The ROSA may further include a cavity wall that is formed on the second TO-CAN stem and that intercepts interference between the separated lights according the polarization.

The ROSA may further include a thermoelectric cooler (TEC) that maintains an ambient temperature of the reflecting mirror.

The TOSA and the ROSA may be coupled in an integral form.

The ROSA may further include a TEC that maintains an ambient temperature of the polarization beam splitter.

The optical fiber current sensor may further include a wavelength delay device that delays a wavelength of polarized light of the TOSA.

The optical fiber current sensor may further include a beam splitter that applies polarized light of the TOSA to the sensor coil and that applies light that is reflected from the sensor coil to the ROSA.

Another embodiment of the present invention provides an optical fiber current sensor that measures a current that flows to a conductor using a sensor coil that is formed with an optical fiber. The optical fiber current sensor includes a beam splitter, a light source, a wavelength delay device, a polarization beam splitter, and a photodetector. The beam splitter separates input light. The light source outputs the light to the beam splitter. The wavelength delay device delays a wavelength of light that is separated by the beam splitter and outputs the light to the sensor coil, and delays a wavelength of light that is reflected from the sensor coil and outputs the light to the beam splitter. The polarization beam splitter separates light that is reflected from the sensor coil according to polarization. The photodetector detects separated light according to polarization. The beam splitter, the polarization beam splitter, the photodetector, and the light source are formed in a package.

The optical fiber current sensor may further include at least one TEC that maintains an ambient temperature of the beam splitter and the polarization beam splitter.

The package may include the at least one TEC.

### BRIEF DESCRIPTION OF THE DRAWINGS

FIG. 1 is a diagram illustrating a principle of an optical current sensor according to an exemplary embodiment of the present invention.

FIG. 2 is a cross-sectional view illustrating an optical fiber current sensor according to an exemplary embodiment of the present invention.

FIG. 3 is a diagram illustrating a ROSA of FIG. 2.

FIG. 4 is a diagram illustrating a method of manufacturing a ROSA of FIG. 2.

FIG. 5 is a graph illustrating output of a first optical fiber current sensor according to an exemplary embodiment of the present invention.

FIG. 6 is a diagram illustrating another example of a ROSA of FIG. 2.

FIG. 7 is a diagram illustrating an optical fiber current sensor according to a second exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

In addition, in the entire specification and claims, unless explicitly described to the contrary, the word “comprise” and variations such as “comprises” or “comprising” will be understood to imply the inclusion of stated elements but not the exclusion of any other elements.

Hereinafter, an optical fiber current sensor according to an exemplary embodiment of the present invention will be described in detail with reference to the drawings.

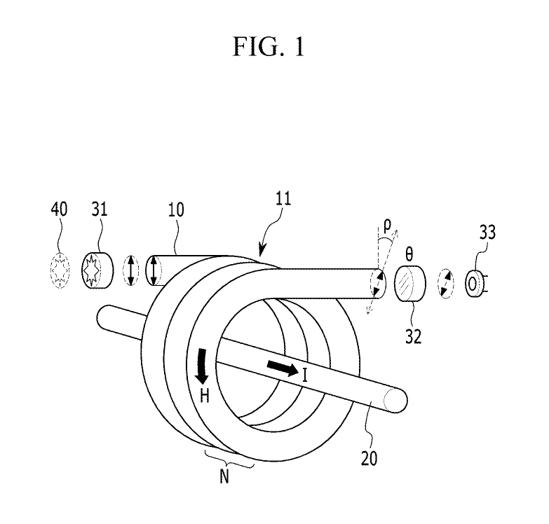

FIG. 1 is a diagram illustrating a principle of an optical current sensor according to an exemplary embodiment of the present invention.

Referring to FIG. 1, the optical current sensor detects a current flowing to a conductor 20 using a circular birefringence change, i.e., a Faraday effect, of an optical fiber 10 that is formed by a magnetic field.

The optical current sensor may include a polarizer 31 that transmits light to a sensor coil 11 that is formed by winding the optical fiber 10 in a closed-loop type at a periphery of the conductor 20, an polarization analyzer 32 that receives light from the sensor coil 11, and two photodetectors 33 that detect the received light.

The polarizer 31 linearly polarizes light from a light source 40 and applies the linearly polarized light to the optical fiber 10.

When the linearly polarized light having passed through the polarizer 31 is applied to the optical fiber 10, while the linearly polarized light advances through the sensor coil 11, a polarization axis rotates by a magnetic field when the magnetic field is formed by a current flowing to the conductor 20, and this is referred to as a Faraday effect. A rotation angle ρ of the polarization axis may be represented by Equation 1.

ρ=VN [symbol] H·dl=VNI (Equation 1)

In Equation 1, V is a Verdet constant and is a constant that determines characteristics of a Faraday element, i.e., a sensor coil. N is the number of times winds of an optical fiber, H is intensity of a magnetic field, and I is a magnitude of a current that flows to the conductor 20.

That is, when performing line integral of a magnetic field in a closed circuit, a current that passes through the closed circuit is obtained. This is difficult to obtain when using a bulk type optical element instead of the optical fiber 10.

Like Equation 1, a rotation angle of a polarization axis caused by a Faraday effect is proportional to a magnitude of a current, i.e., intensity of a magnetic field flowing to the conductor 20, and by measuring a rotation angle ρ, a magnitude of a current flowing to the conductor 20 may be measured.

When an angle between the polarizer 31 and the polarization analyzer 32 is θ, an output of a sensor coil has nonlinear transfer characteristics of cos²θ. Therefore, at θ=−45°, because an output having linearity and high sensitivity may be obtained, an angle between the polarizer 31 and the polarization analyzer 32 may be set to correspond to −45°.

The polarization analyzer 32 separates output light of a sensor coil according to polarization, and light that is separated according to polarization is detected by the two photodetectors 33.

The two photodetectors 33 convert light that is separated according to polarization to a current value corresponding to an electric signal. When an output of the two photodetectors 33 is referred to as I₁ and I₂, a rotation angle ρ may be calculated by Equation 2 from an output of the two photodetectors 33.

$$S = \frac{{I}_{1} - {I}_{2}}{{I}_{1} + {I}_{2}} = sin 2 ρ \approx 2 ρ \qquad ( Equation 2 )$$

That is, a signal of an output of the two photodetectors 33 is processed by an embedded computer and thus a rotation angle ρ is calculated and intensity of a current may be determined from the calculated rotation angle ρ.

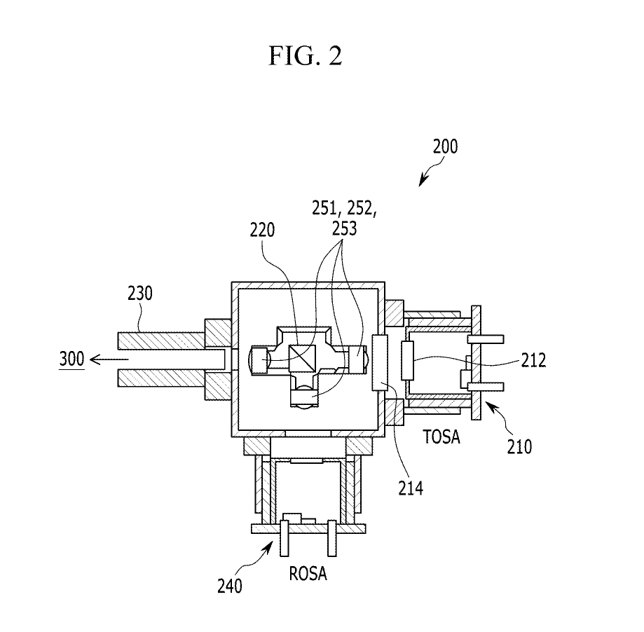

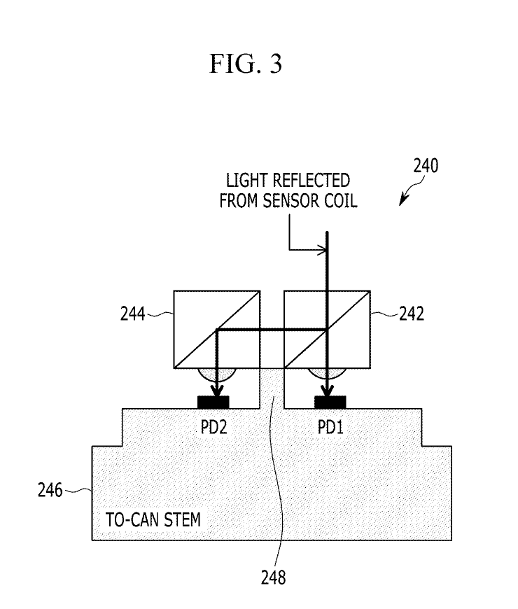

FIG. 2 is a cross-sectional view illustrating an optical fiber current sensor according to an exemplary embodiment of the present invention, and FIG. 3 is a diagram illustrating an example of a receiver optical subassembly (ROSA) of FIG. 2.

Referring to FIGS. 2 and 3, an optical fiber current sensor 200 includes a transmitter optical subassembly (TOSA) 210, a beam splitter 220, an optical fiber sensor connector 230, and a ROSA 240.

The TOSA 210 performs a light transmitting operation and is formed in a TO-CAN package for downsizing. The TOSA 210 includes a linear polarizer 212 and a wavelength delay device 214 corresponding to the polarizer of FIG. 1. The linear polarizer 212 linearly polarizes and outputs light from a light source, and is mounted on a TO-CAN stem for downsizing.

The wavelength delay device 214 is integrally formed with the TOSA 210 and delays linearly polarized light by a half wavelength or a quarter wavelength. Such a wavelength delay device 214 performs a function of adjusting a vibration axis of linear polarized light to form an angle of 45° or −45° from a polarization beam splitter 242 of the TOSA 210.

The beam splitter 220 has a separation ratio of 50:50, and separates linearly polarized light that is delayed by the wavelength delay device 214 and applies the light to a sensor coil 300.

The sensor coil 300 is the same as the sensor coil 11 of FIG. 1, is a reflective sensor coil, and may be formed in various optical fiber spools. For a reflective sensor coil, reflection coating processing may be performed in an end portion of the optical fiber 10 or a reflecting mirror may be mounted in an end portion of the optical fiber 10. Therefore, light that is applied to the sensor coil is reflected while passing through the sensor coil, and light that is reflected from the sensor coil 300 is reflected from the beam splitter 220 to be applied to the ROSA 240.

A focus lens 251 may be positioned between the beam splitter 220 and the sensor coil 300 so that light that is separated by the beam splitter 220 is accurately applied to the sensor coil 300. Further, a focus lens 252 may be positioned between the beam splitter 220 and the ROSA 240 so that light that is reflected from the sensor coil 300 is accurately applied to the ROSA 240, and a focus lens 253 may be positioned between the wavelength delay device 214 and the beam splitter 220 so that linearly polarized light that is delayed by the wavelength delay device 214 is accurately applied to the beam splitter 220.

In this case, the TOSA 210 and the ROSA 240 may form a bidirectional optical subassembly (BOSA) that is coupled in one form. That is, the linear polarizer 212, the wavelength delay device 214, the polarization beam splitter 242, a reflecting mirror 244, and photodiodes PD1 and PD2 may be formed on a TO-CAN stem. Alternatively, the TOSA 210 and the ROSA 240 may form respective an OSA.

The optical fiber sensor connector 230 is used to connect the optical fiber current sensor 200 to the sensor coil 300, and is coupled to and decoupled from the sensor coil 300. An optical fiber sensor connector 230 may exist in a BOSA.

FIG. 1 illustrates the optical fiber sensor connector 230 as a receptacle type, but the optical fiber sensor connector 230 may be formed in a pigtail structure. The ROSA 240 performs a light reception operation. The ROSA 240 receives light that is reflected from the beam splitter 220, and is formed in a TO-CAN package for downsizing.

Specifically, as shown in FIG. 3, the ROSA 240 includes the polarization beam splitter 242 corresponding to the polarization analyzer 32 of FIG. 1, the reflecting mirror 244, and photodiodes PD1 and PD2 corresponding to the two photodetectors 33 of FIG. 1.

The polarization beam splitter 242 and the reflecting mirror 244 are mounted on a TO-CAN stem 246. The polarization beam splitter 242 receives light that is applied to the ROSA 240, and separates the received light in an x-axis direction and a y-axis direction according to polarization. The polarization beam splitter 242 outputs light separated in an x-axis direction, and changes a polarization direction of separated light by 90° and outputs it in a y-axis direction according to polarization. Light that is separated in the x-axis direction is applied to the photodiode PD1, and light of which a polarized direction is changed by 90° is reflected by the reflecting mirror 244 to be applied to the photodiode PD2.

The photodiodes PD1 and PD2 are mounted at a predetermined gap on the TO-CAN stem 246, detect light that is separated according to polarization, and convert and output the detected light with a current value corresponding to an electric signal. In this case, in order to minimize interference between separated light according to a polarization axis of the polarization beam splitter 242, a cavity wall 248 may be installed on the TO-CAN stem 246.

In this way, by mounting an optical element such as the linear polarizer 212 or the polarization beam splitter 242, the reflecting mirror 244, and the photodiodes PD1 and PD2 on the TO-CAN stem, a structure of the optical fiber current sensor 200 is simplified and the optical fiber current sensor 200 can be produced in a microsize and can be mass-produced with a low cost.

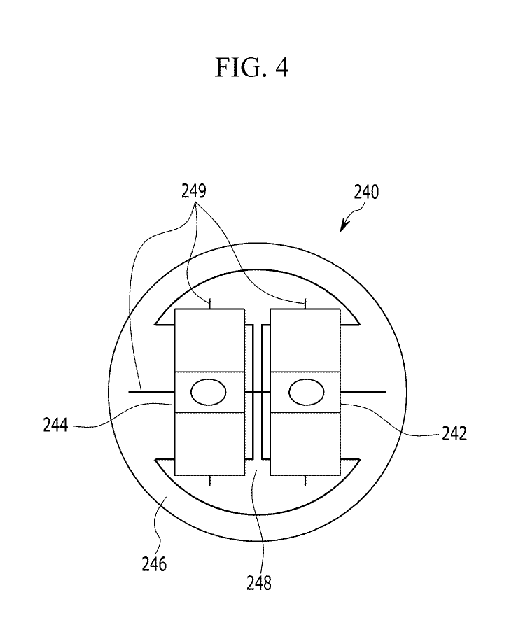

FIG. 4 is a diagram illustrating a method of manufacturing a ROSA of FIG. 2.

Referring to FIG. 4, light that is applied to the ROSA 240 is separated according to a polarization axis of the polarization beam splitter 242, and the polarization beam splitter 242 and the reflecting mirror 244 are aligned to detect the separated light by the photodiodes PD1 and PD2. In this case, in order to minimize an alignment error of the polarization beam splitter 242 and the reflecting mirror 244, after fixing the polarization beam splitter 242 and the reflecting mirror 244 on the TO-CAN stem 246 using an alignment mark 249, the polarization beam splitter 242 and the reflecting mirror 244 are attached to the TO-CAN stem 246 using UV epoxy. The cavity wall 248 may be formed between the polarization beam splitter 242 and the reflecting mirror 244.

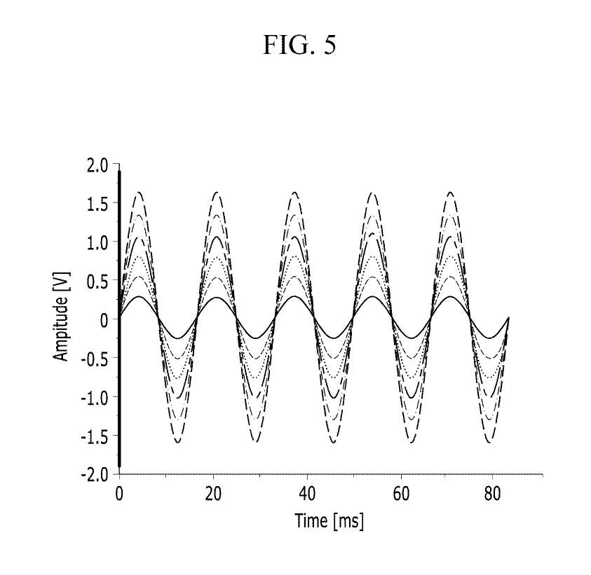

FIG. 5 is a graph illustrating an output of an optical fiber current sensor according to an exemplary embodiment of the present invention, and illustrates an output waveform of a measured optical fiber current sensor while increasing a current by 500 AT to 500-2500 AT.

As shown in FIG. 5, it can be determined that an output waveform of the optical fiber current sensor 200 is well restored as a 60 Hz AC signal.

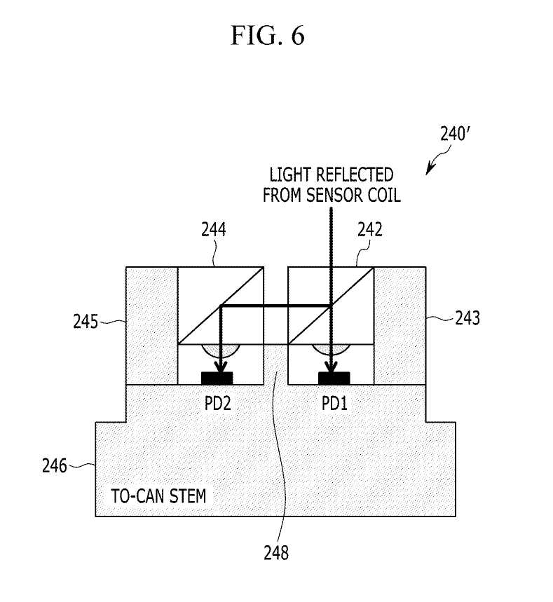

FIG. 6 is a diagram illustrating another example of a ROSA of FIG. 2.

Referring to FIG. 6, a ROSA 240′ further includes TEC thermoelectric coolers 243 and 245 in the ROSA 240 of FIG. 3.

The TECs 243 and 245 are positioned at one side of the polarization beam splitter 242 and the reflecting mirror 244, respectively, and constantly maintain a temperature of the polarization beam splitter 242 and the reflecting mirror 244 by absorbing ambient heat of the polarization beam splitter 242 and the reflecting mirror 244.

In a short wavelength light source, a separation ratio of wavelength characteristics and an optical element (e.g., a beam splitter, a polarization beam splitter, etc.) and light transmission characteristics are changed according to temperature. When the temperature changes, polarization characteristics or reflection characteristics of the polarization beam splitter 242 and the reflecting mirror 244 may be changed. Therefore, by constantly maintaining the ambient temperature of the polarization beam splitter 242 and the reflecting mirror 244 using the TEC 243 and 245, polarization characteristics or reflection characteristics are not changed by the ambient temperature of the polarization beam splitter 242 and the reflecting mirror 244.

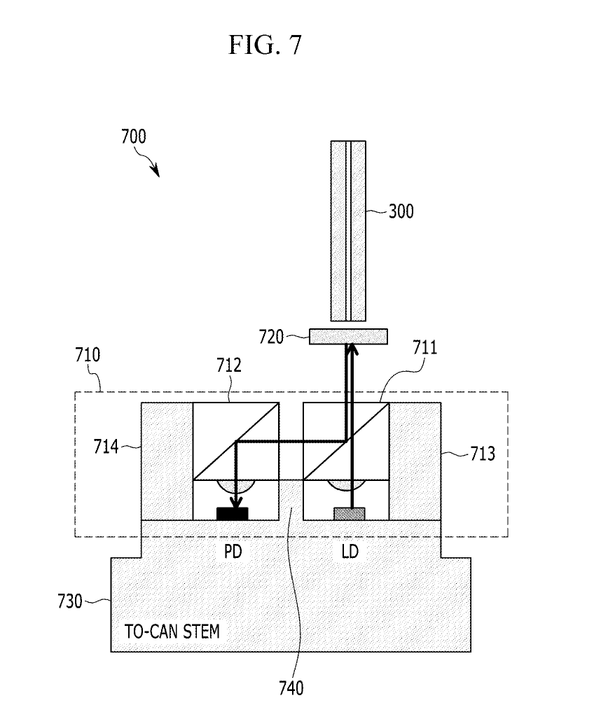

FIG. 7 is a diagram illustrating an optical fiber current sensor according to a second exemplary embodiment of the present invention.

Referring to FIG. 7, an optical fiber current sensor 700 includes an optical subassembly (OSA) 710 and a wavelength delay device 720.

The OSA 710 performs a light transmitting/receiving operation, and may be mounted on a TO-CAN stem 730. The OSA 710 may include a laser diode, a beam splitter 711, a polarization beam splitter 712, a photodiode PD, and TECs 713 and 714.

The laser diode LD is a light source and outputs light.

The beam splitter 711 has the same function as that of the beam splitter 220 of FIG. 2. The beam splitter 711 separates light from the LD and outputs the separated light to the wavelength delay device 720, and separates light from the wavelength delay device 720 and outputs the separated light to the polarization beam splitter 712.

The wavelength delay device 720 delays light that is separated by the beam splitter 711 by a half wavelength or a quarter wavelength, applies the delayed light to a sensor coil 300, and delays light that is reflected from the sensor coil 300 by a half wavelength or a quarter wavelength and outputs the delayed light to the beam splitter 711.

The polarization beam splitter 712 separates received light according to polarization.

The photodiode (PD) detects separated light according to polarization by the polarization beam splitter 242, and converts and outputs the detected light with a current value corresponding to an electrical signal. In this case, in order to minimize interference between the transmitted/received light, a cavity wall 740 may be installed on the TO-CAN stem 730.

The TECs 713 and 714 are positioned at one side of the beam splitter 711 and the polarization beam splitter 712, respectively, absorb ambient heat of the beam splitter 711 and the polarization beam splitter 712, and constantly maintain the temperature of the beam splitter 711 and the polarization beam splitter 712.

In this way, as light transmission and light reception are processed by one OSA, a structure of the optical fiber current sensor may be further simplified.

In an exemplary embodiment of the present invention, a package form is described as a TO-CAN, but an optical fiber current sensor may be formed in a package of a different form.

According to an exemplary embodiment of the present invention, by mounting an optical element on a TO-CAN, a structure of an optical current sensor is simplified, and by manufacturing the optical current sensor in a microsize, the optical fiber current sensor can be mass-produced with a low cost. Further, because a solution of a TO-CAN form is provided, an optical fiber current sensor can be easily applied to a small-sized polarization measurement based-optical sensor application product of various forms in addition to a current sensor.

An exemplary embodiment of the present invention may not be only embodied through the above-described apparatus and/or method, but may also be embodied through a program that executes a function corresponding to a configuration of the exemplary embodiment of the present invention or through a recording medium on which the program is recorded, and can be easily embodied by a person of ordinary skill in the art from a description of the foregoing exemplary embodiment.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An optical fiber current sensor that measures a current that flows to a conductor using a sensor coil that is formed with an optical fiber, the optical fiber current sensor comprising:
a transmitter optical subassembly (TOSA) that polarizes light from a light source and that applies the light to the sensor coil; and
a receiver optical subassembly (ROSA) that separates light that is reflected from the sensor coil according to polarization and that detects the separated light according to polarization,
wherein the TOSA and the ROSA are formed in a transistor outline (TO)-CAN package.

2. The optical fiber current sensor of claim 1, wherein the TOSA comprises a linear polarizer that is formed on a first TO-CAN stem and that linearly polarizes light from the light source and applies the light to the sensor coil.

3. The optical fiber current sensor of claim 1, wherein the ROSA comprises:
a polarization beam splitter that is formed on a second TO-CAN stem and that separates light that is reflected from the sensor coil according to polarization; and
first and second photodiodes that are each formed on the second TO-CAN stem and that detect separated light according to polarization.

4. The optical fiber current sensor of claim 3, wherein the ROSA further comprises a reflecting mirror that reflects one of the separated lights according to polarization and that applies the light to a second photodiode.

5. The optical fiber current sensor of claim 4, wherein the ROSA further comprises a cavity wall that is formed on the second TO-CAN stem and that intercepts interference between the separated lights according the polarization.

6. The optical fiber current sensor of claim 4, wherein the ROSA further comprises a thermoelectric cooler (TEC) that maintains an ambient temperature of the reflecting mirror.

7. The optical fiber current sensor of claim 3, wherein the TOSA and the ROSA are coupled in an integral form.

8. The optical fiber current sensor of claim 2, wherein the ROSA further comprises a TEC that maintains an ambient temperature of the polarization beam splitter.

9. The optical fiber current sensor of claim 1, further comprising a wavelength delay device that delays a wavelength of polarized light of the TOSA.

10. The optical fiber current sensor of claim 9, wherein the wavelength delay device delays the polarized light by a half wavelength or a quarter wavelength.

11. The optical fiber current sensor of claim 1, further comprising a beam splitter that applies polarized light of the TOSA to the sensor coil and that applies light that is reflected from the sensor coil to the ROSA.

12. The optical fiber current sensor of claim 1, further comprising a connector for coupling to the sensor coil.

13. An optical fiber current sensor that measures a current that flows to a conductor using a sensor coil that is formed with an optical fiber, the optical fiber current sensor comprising:
a beam splitter that separates input light;
a light source that outputs the light to the beam splitter;
a wavelength delay device that delays a wavelength of light that is separated by the beam splitter, outputs the light to the sensor coil and delays a wavelength of light that is reflected from the sensor coil, and outputs the light to the beam splitter;
a polarization beam splitter that separates light that is reflected from the sensor coil according to polarization; and
a photodetector that detects separated light according to the polarization,
wherein the beam splitter, the polarization beam splitter, the photodetector, and the light source are formed in a package.

14. The optical fiber current sensor of claim 13, further comprising at least one TEC that maintains an ambient temperature of the beam splitter and the polarization beam splitter.

15. The optical fiber current sensor of claim 13, wherein the package comprises the at least one TEC.

16. The optical fiber current sensor of claim 13, wherein the package comprises a TO-CAN package.

17. The optical fiber current sensor of claim 13, wherein the light source comprises a laser diode.

18. The optical fiber current sensor of claim 13, wherein the wavelength delay device delays input light by a half wavelength or a quarter wavelength.
